(19) United States
(12) Patent Application Publication
(10) Pub. No.: US 2026/0011365 A1
(43) Pub. Date: Jan. 8, 2026

(54) TRACKING CIRCUITS FOR CROSSBAR CIRCUITS

(71) Applicant: TetraMem Inc., San Jose, CA (US)

(72) Inventors: Wenbo Yin, Alameda, CA (US); Hengfang Zhu, Fremont, CA (US); James Boley, San Francisco, CA (US)

(73) Assignee: TetraMem Inc., San Jose, CA (US)

(21) Appl. No.: 19/261,116

(22) Filed: Jul. 7, 2025

Related U.S. Application Data
(60) Provisional application No. 63/668,294, filed on Jul. 7, 2024.

(51) Int. Cl. G11C 13/00

(52) U.S. Cl. CPC G11C 13/004; G11C 13/0038

(57) ABSTRACT

Described herein are techniques to enable tracking circuits for crossbar circuits. One embodiment provides an apparatus including a crossbar array comprising: a plurality of bit lines intersecting with a plurality of word lines; and a plurality of cross-point devices, wherein each of the cross-point devices is connected to at least one of the word lines and at least one of the bit lines; a read-out circuit selectively connected to at least one of the bit lines, wherein the read-out circuit is to generate an output representative of the memristor conductance; a tracking circuit comprising a first replica cell that emulates at least one of the cross-point devices, wherein the tracking circuit is to produce a reference voltage; and a converter configured to convert the output of the read-out circuit into a digital output or a pulse-width-modulated signal, wherein the reference voltage is provided to the converter as an input.

### CROSS-REFERENCE TO RELATED APPLICATIONS

The present application claims the benefits of U.S. Provisional Application No. 63/668,294, entitled “TRACKING CIRCUITS FOR CROSSBAR CIRCUITS,” filed Jul. 7, 2024, which is incorporated herein in its entirety.

### TECHNICAL FIELD

The implementations of the disclosure relate generally to electronic circuits and, more specifically, to tracking circuits for tracking and compensating for process, voltage, and temperature (PVT) variations of a crossbar array.

### BACKGROUND

A crossbar circuit may refer to a circuit structure with interconnecting electrically conductive lines sandwiching a memory element, such as a resistive switching material, at their intersections. Crossbar circuits may be used to implement in-memory computing applications, non-volatile solid-state memory, image processing applications, neural networks, etc.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a diagram illustrating an example of a crossbar circuit in accordance with some embodiments of the present disclosure.

FIGS. 2A and 2B are schematic diagrams illustrating example cross-point devices in accordance with some embodiments of the present disclosure.

FIG. 3 is a block diagram depicting an example tracking circuit in accordance with some embodiments of the present disclosure.

FIG. 4 is a block diagram depicting an example tracking circuit in accordance with another implementation of the present disclosure.

FIG. 5 is a block diagram depicting an example tracking circuit in accordance with a further implementation of the present disclosure.

FIG. 6 is a block diagram depicting an example tracking circuit in accordance with a further implementation of the present disclosure.

### DESCRIPTION

The implementations of the disclosure relate generally to electronic circuits and, more specifically, to tracking circuits for tracking and compensating for process, voltage, and temperature (PVT) variations of a crossbar array. The tracking circuit described herein may be incorporated into crossbar circuits for memory applications, in-memory computing, etc.

A crossbar circuit may refer to a circuit structure with interconnecting electrically conductive lines sandwiching a memory element, such as a resistive switching material, at their intersections. The resistive switching material may include, for example, a memristor (also referred to as resistive random-access memory (RRAM or ReRAM)). Crossbar circuits may be used to implement in-memory computing applications, non-volatile solid-state memory, image processing applications, neural networks, etc.

ReRam-based memory circuits typically convert a conductance value into a voltage by using an I-V read driver first. Subsequently, an ADC is used to convert this voltage to a digital output. In a single-bit ReRam, the sensitivity to process variation is low because the noise margin is approximately half of the supply voltage. However, in a multi-bit ReRam, the sensitivity to temperature and power supply variation is higher due to the smaller noise margin. For example, a 6-bit ReRam with an ADC input range of 400 mV requires an accuracy of 6.25 mV to prevent read bit errors. The higher sensitivity of the multi-bit ReRam cell to temperature and input voltage variation necessitates the inclusion of a compensation circuit to prevent read bit errors.

The tracking mechanisms described herein employ a replica cell and/or a replica array to track the process, voltage, and temperature (PVT) variations of a crossbar array (also referred to as the core array). The replica cell may include one or more cross-point devices that are connected to a bit line that is not part of the core array and one or more word lines of the core array. The replica cell may utilize the minimum, middle, or maximum conductance of the ReRam cell to generate reference voltages, which track changes due to voltage and temperature in real-time.

As an example, a common mode voltage (VCM) tracking circuit may include a programmable resistor or memristor set to the mid-conductance value of the ReRam array to monitor the average value of the output voltage. As another example, a range tracking circuit may employ two replica read driver circuits in combination with programmable resistors or memristors set to the minimum and maximum conductance values of the ReRam array to track the output voltage range. The output of the range tracking circuit may be provided to an ADC as a reference voltage defining the full voltage range of the ADC. As a further example, a leakage current tracking circuit may mirror the leakage current in the ReRam array and compensate for the leakage current in the core array.

The mechanisms described herein may offer improved voltage and temperature variation robustness by reducing read-bit errors due to PVT variations through the addition of a tracking circuit. They may also ensure low power and area overhead since the replica circuit is instantiated only once, resulting in an area and power overhead that is roughly proportional to 1 divided by the number of slices. Furthermore, the mechanisms described herein may provide high accuracy, real-time temperature and voltage compensation using a replica circuit. This replica circuit closely tracks the core ReRam array behavior, leading to improved matching between the tracking array and the core memory array.

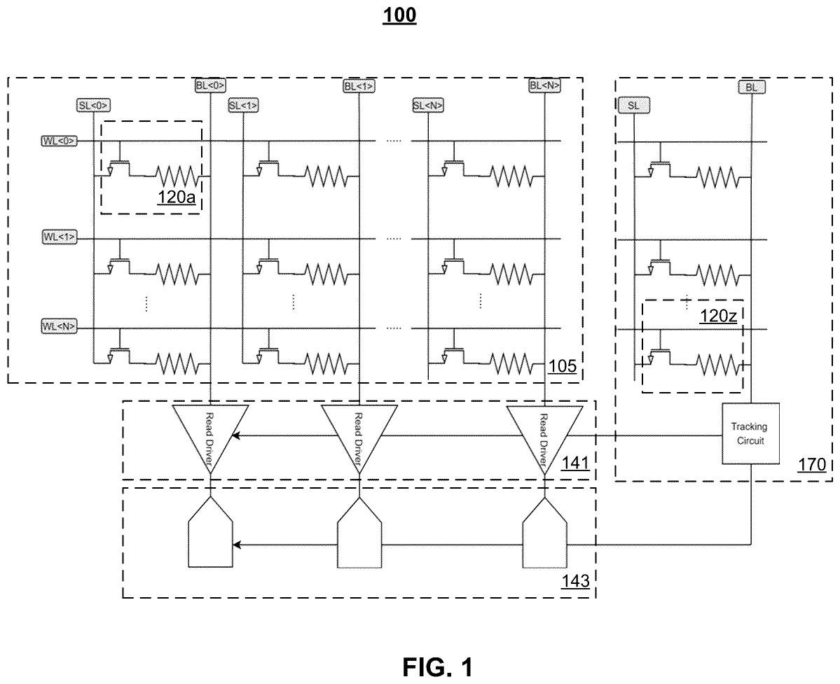

FIG. 1 is a diagram illustrating an example 100 of a crossbar circuit in accordance with some embodiments of the present disclosure. As shown, crossbar circuit 100 may include a crossbar array 105 including a plurality of interconnecting electrically conductive wires, such as word lines WL<0>, WL<1>, . . . , WL<N>, bit lines BL<0>, BL<1>, . . . , BL<N>, and source lines SL<0>, SL<1>, . . . , SL<N>. Crossbar array 105 may further include cross-point devices 120a, . . . , 120z, etc. Each of the cross-point devices may connect a row wire and a column wire. The number of the word lines and the bit lines may or may not be the same. Each of the word lines and the bit lines may be and/or include any suitable electrically conductive material.

Crossbar circuit 100 may further include a word line (WL) logic (not shown) that is connected to the cross-point devices via the WL<0>, WL<1>, . . . , WL<N>. The WL logic may include any suitable component for applying input signals to selected cross-point devices via word lines, such as one or more digital-to-analog converters (DACs), amplifiers, etc. Each of the input signals may be a voltage signal, a current signal, etc.

Each cross-point device 120a-120z may be and/or include any suitable device with tunable resistance, such as a memristor, phase-change memory (PCM) devices, floating gates, spintronic devices, ferroelectric devices, RRAM devices, etc.

Each word line may be connected to one or more row switches (not shown). Each row switch may include any suitable circuit structure that may control the current flowing through word lines. For example, row switches may be and/or include a CMOS switch circuit.

Each bit line may be connected to one or more column switches (not shown). Each column switch may include any suitable circuit structure that may control current passing through bit lines. For example, the column switches may be and/or include a CMOS switch circuit. In some embodiments, one or more row switches and/or column switches may further provide fault protection, electrostatic discharge (ESD) protection, noise reduction, and/or any other suitable function for one or more portions of crossbar circuit 100.

Crossbar circuit 100 may further include one or more read-out circuits 141 (also referred to as “read drivers”) that may generate an output representative of the memristor conductance of the cross-point devices connected to a bit line and converters 143 that may convert output voltages of read-out circuits 141 into outputs. Read-out circuit 141 may convert the BL current to an output voltage. A converter 143 may be and/or include an analog-to-digital converter (ADC), a pulse width modulator, a TDC (time-to-digital converter), and/or any other suitable circuitry that can convert the outputs of the read-out circuits 141 into output signals. An ADC may convert the output voltage of a read-out circuit 141 into a digital output. A pulse width modulator may convert the output voltage of a read-out circuit 141 into a pulse-width-modulated signal. A TDC may convert the output voltage of a read-out circuit 141 into a digital output by first measuring the time interval corresponding to the voltage level and then converting that time interval into a digital output.

Programming a cross-point device may involve applying a suitable voltage signal or current signal across the cross-point device. The resistance of each cross-point device may be electrically changed between high-resistance and low-resistance. Setting a cross-point device may involve changing the resistance of the cross-point from high-resistance to low-resistance. Resetting the cross-point device may involve changing the resistance of the cross-point from low-resistance to high-resistance.

Crossbar circuit 100 may perform parallel weighted voltage multiplication. For example, an input voltage signal may be applied to one or more rows of crossbar array 105 (e.g., one or more selected word lines). The input signal may flow through the cross-point devices of the rows of the crossbar array 105. The conductance of the cross-point device may be tuned to a specific value (also referred to as a “weight”). By Ohm's law, the input voltage multiplies the cross-point conductance and generates a current from the cross-point device. By Kirchhoff's law, the sum of the currents passes through the activated cross-point devices on a respective column (also referred to as the “bit line current”), which may be read from the column. According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current (the “bit line current”) is output via each column wire and may be accumulated according to Kirchhoff's current law. This may enable in-memory computing (IMC) via parallel multiplications and summations performed in the crossbar arrays.

Crossbar circuit 100 may be configured to perform vector-matrix multiplication (VMM). A VMM operation may be represented as Y=XA, wherein each of Y, X, A represents a respective matrix. More particularly, for example, input vector X may be mapped to the input voltage V of crossbar array 105. Matrix A may be mapped to conductance values G. The output current I may be read and mapped back to output results Y. In some embodiments, crossbar circuit 100 may be configured to implement a portion of a neural network by performing VMMs.

In some embodiments, crossbar circuit 100 may perform convolution operations. For example, performing 2D convolution on input data may involve applying a single convolution kernel to the input signals. Performing a depthwise convolution on the input data may involve convolving each channel of the input data with a respective kernel corresponding to the channel and stacking the convolved outputs together. The convolution kernel may have a particular size defined by multiple dimensions (e.g., a width, a height, a channel, etc.). The convolution kernel may be applied to a portion of the input data of the same size to produce an output. The output may be mapped to an element of the convolution result that is located at a position corresponding to the position of the portion of the input data.

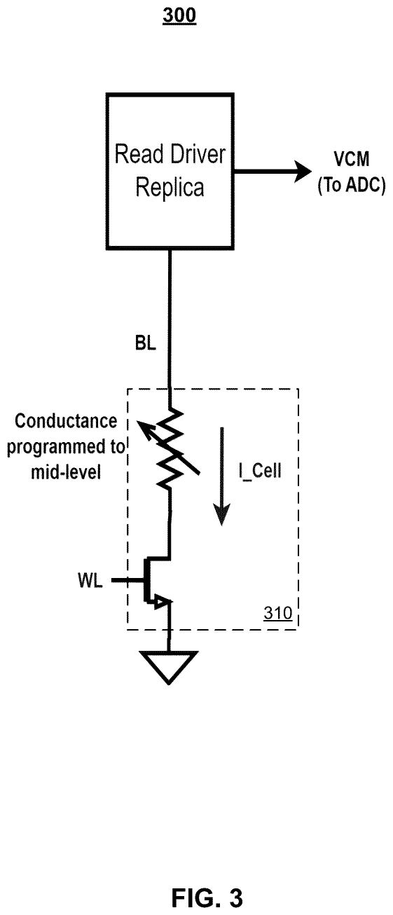

Crossbar circuit 100 further includes a tracking circuit 170 that may track temperature and voltage supply variations and generate an output to compensate for variations in the outputs of read-out circuits 141 caused by the variations across PVT. Tracking circuit 170 may include one or more replica cells that may emulate the behavior of a cross-point device in crossbar array 105. In some embodiments, tracking circuit 170 may include an array of replica cells (also referred to as the “replica array”). Tracking circuit 170 may further include one or more read driver replicas that may emulate or mimic the operations and functions of a read-out circuit 141. In some embodiments, the tracking circuit 170 may include one or more tracking circuits as described in connection with FIGS. 3-6 below.

To track the temperature and voltage supply variations, the tracking circuit may employ a replica read path that monitors changes in the output voltage in real time. The output of the tracking circuit can be utilized in several configurations, such as tuning the read driver circuit to maintain a specified output voltage, adjusting the ADC input parameters to maintain a specified ADC output code, and tuning the pulse generation circuit to maintain a specified pulse width.

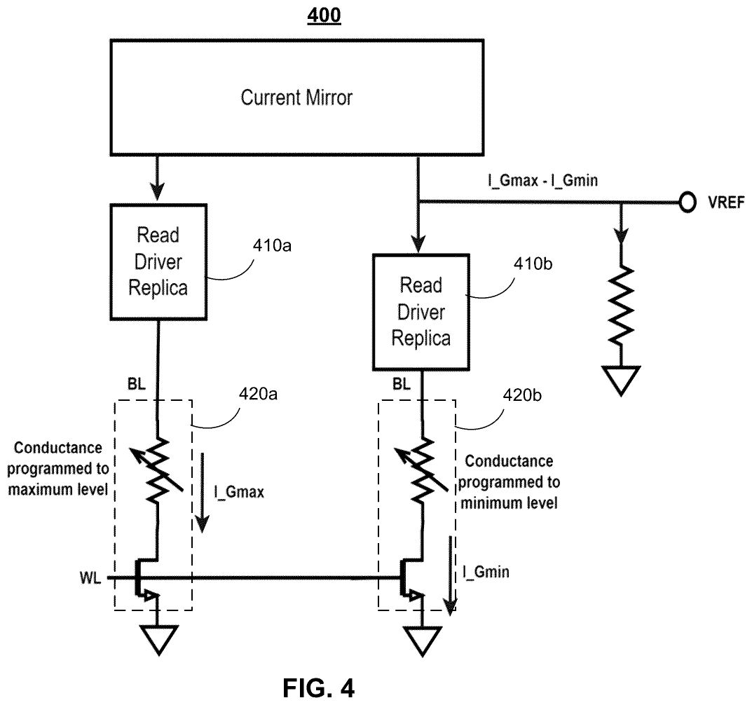

In one implementation, the converters 143 may include an ADC. The ADC's reference voltage range should align with the outputs of the read-out circuits 141. Tracking circuit 170 may provide a bias voltage to the ADC, compensating for global voltage and temperature effects. For example, as described in greater detail in connection with FIG. 3, the output of the tracking circuit may be provided to the converter(s) as a VCM (common-mode voltage). As another example, as described in greater detail in connection with FIG. 4, the output of the tracking circuit may be provided to the converter(s) as a voltage VREF that represents the full voltage range of the ADC.

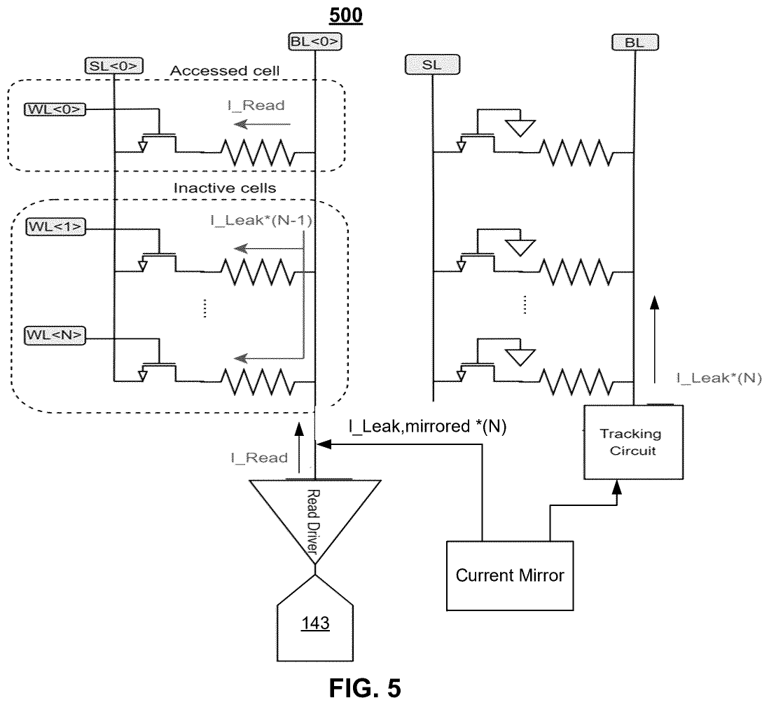

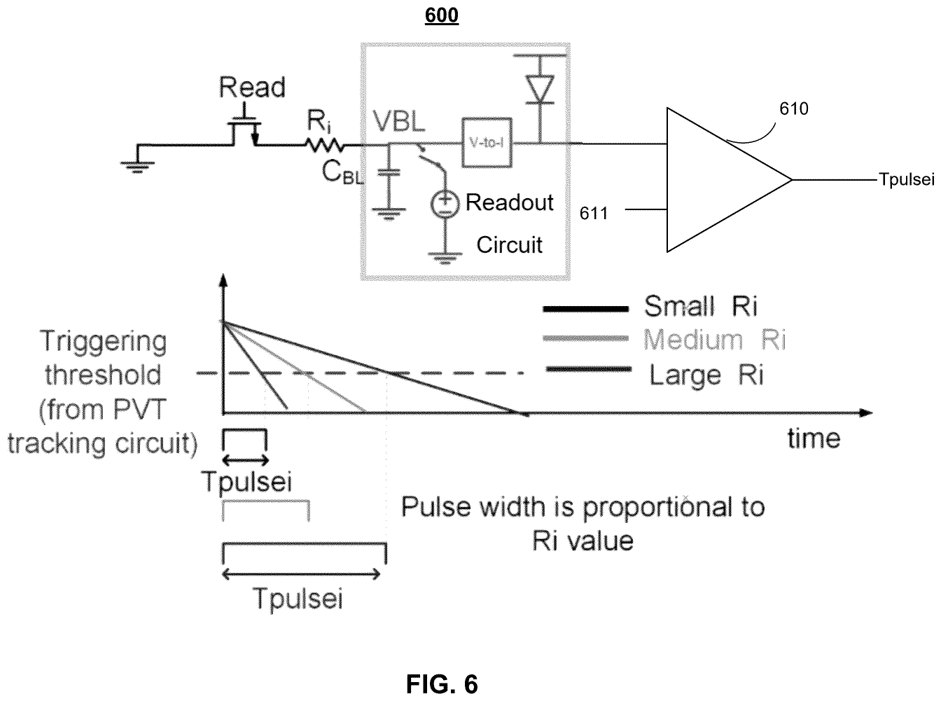

In some embodiments, as described in greater detail in connection with FIG. 5, the output of tracking circuit 170 may be used to compensate for the leakage current of the inactive cells in crossbar array 105. In some embodiments, as described in greater detail in connection with FIG. 6, the output of tracking circuit 170 may be provided to converter(s) 143 as a triggering threshold voltage, where converter(s) 143 are configured to perform weight-to-pulse width conversion using a level-crossing detector (e.g., a comparator). The tracking circuits and mechanisms described herein may be used to compensate for varying outputs of read-out circuit 141 caused by PVT variations in some embodiments in which the converters 143 include a TDC configured to convert the output voltage of a read-out circuit 141 into a digital output by first measuring the time interval corresponding to the voltage level and then converting that time interval into a digital output.

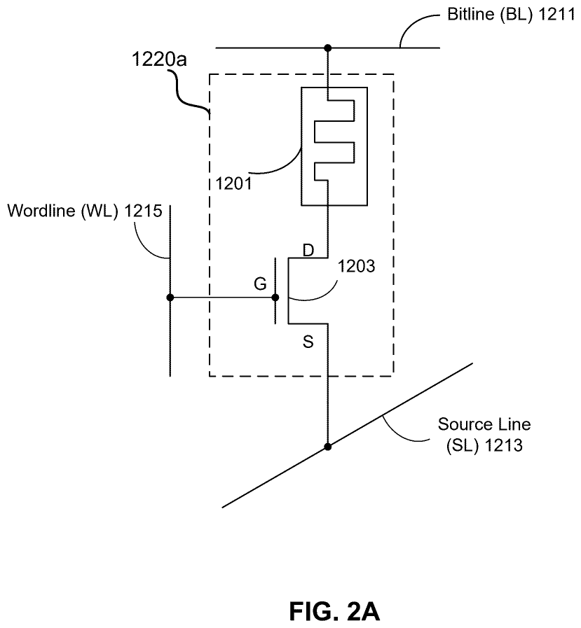

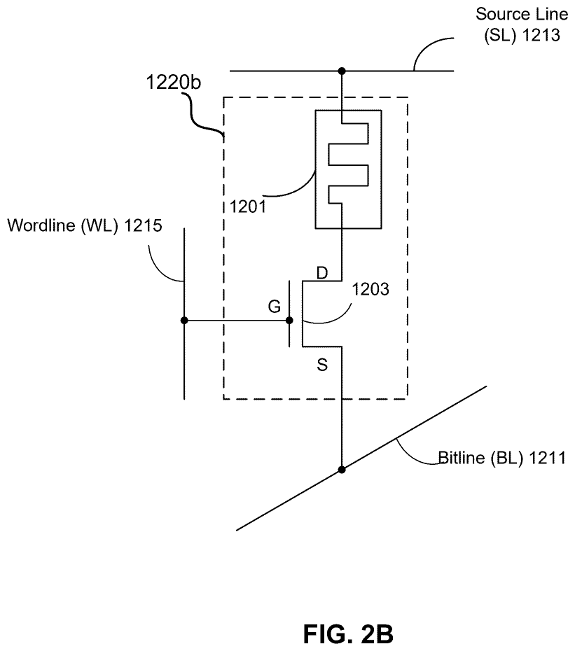

FIGS. 2A and 2B are schematic diagrams illustrating example cross-point devices 1220a and 1220b in accordance with some embodiments of the present disclosure. Cross-point device 1220a and cross-point device 1220b may be referred to as a 1-transistor-1-resistor (1T1R) configuration.

As shown in FIGS. 2A and 2B, a cross-point device 1220a or 1220b may include an RRAM device 1201 and a transistor 1203 that are connected in series. A transistor may include four terminals that may be marked as gate (G), source (S), drain (D), and bulk (B) (not shown in FIGS. 2A and 2B), respectively. Referring to FIG. 2A, the first terminal of RRAM device 1201 may be connected to the drain of transistor 1203. A second terminal of RRAM device 1201 may be connected to a bit line 1211. The gate of the transistor 1203 may be connected to a word line 1215. The source of transistor 1203 may be connected to a source line (SL) 1213.

As shown in FIG. 2B, the second terminal of RRAM device 1201 may be connected to the source line 1213, and the source of the transistor 1203 may be connected to a bit line 1211 in some embodiments. Word line 1215 may correspond to a word line of FIG. 1. Bit line 1211 may correspond to a bit line of FIG. 1.

Transistor 1203 may function as a selector as well as a current controller and may set the current compliance to RRAM device 1201 during programming. The gate voltage on transistor 1203 can set current compliances to cross-point device 1220a-b during programming and can thus control the conductance and analog behavior of cross-point device 1220a-b. For example, when cross-point device 1220a-b is set from a high-resistance state to a low-resistance state, a set signal (e.g., a voltage signal, a current signal) may be provided via bit line (BL) 1211 or word line (WL) 1215. Another voltage, also referred to as a select voltage or gate voltage, may be applied via source line (SL) 1213 to the transistor gate to open the gate and set the current compliance, while word line (WL) 1215 or bit line (BL) 1211 may be grounded. When cross-point device 1220a-b is reset from the low-resistance state to the high-resistance state, a gate voltage may be applied to the gate of transistor 1203 via source line 1213 to open the transistor gate. Meanwhile, a reset signal may be sent to RRAM device 1201 via word line 1215 or bit line 1211, while bit line 1211 or word line 1215 may be grounded.

FIG. 3 is a block diagram depicting an example tracking circuit 300 in accordance with some embodiments of the present disclosure.

As shown, tracking circuit 300 may include a read driver replica that is connected to a replica cell 310. The replica cell may be connected to a bit line BL and a word line WL. The word line WL may be a word line in crossbar array 105. The read driver replica is a replica of a read-out circuit 141 and may produce an output representative of the current flowing through BL.

A word line voltage may be applied to the replica cell as well as the cross-point devices in crossbar array 105 that are connected to WL via WL. The read path is thus a replica core array. As such, all non-idealities in the crossbar array 105 (e.g., select mux resistance, read driver non-linearities, array leakage, etc.) may be tracked.

The replica cell may include a cross-point device that is programmed to have a conductance representative of the average conductance of the cross-point devices of crossbar array 105. The current through the replica cell (I_Cell) may thus correspond to the bit line current in response to the word line voltage when the cross-point devices of crossbar array 105 are programmed to the mid-level conductance value. The output of the read driver replica may be provided to an ADC as a VCM that represents the midpoint of the full range of the ADC. The proposed circuit tracks the VCM voltage in real-time to adjust the middle level of the ADC range.

FIG. 4 is a block diagram depicting an example tracking circuit 400 in accordance with another implementation of the present disclosure. Tracking circuit 400 may produce an output voltage that may be provided to a converter 143 as a reference voltage VREF. In some embodiments, the converter 143 comprises an ADC. VREF may represent the input voltage range of the ADC.

As shown, tracking circuit 400 may include a first read driver replica 410a and a second read driver replica 410b. The first read driver replica 410a is connected to a first replica cell 420a. The second read driver replica 410b may be connected to a second replica cell 420b. The first read driver replica 410a and the second read driver replica 410b are connected to a current mirror. The first replica cell 420a is connected to a word line WL and a first bit line. The second replica cell 420b is connected to the word line WL and a second bit line.

The first replica cell 420a may include one or more cross-point devices programmed to the maximum conductance of the cross-point devices in the crossbar array. The second replica cell 420b may include one or more cross-point devices programmed to the minimum conductance of the cross-point devices in the crossbar array. As such, the first read driver replica 410a may produce a first output current representing the maximum bit line current (I_Gmax) in response to the WL voltage in the crossbar array 105. The second read driver replica 410b may produce a second output current representing the minimum bit line current (I_Gmin) in response to the WL voltage in the crossbar array. The minimum bitline current (I_Gmin) is subtracted from the output of the current mirror (I_Gmax) to produce the difference current (I_Gmax−I_Gmin). Tracking circuit 400 may further include one or more resistors and/or any other suitable components for converting the output current of the current mirror 430 into output voltage VREF. The output voltage VREF may thus correspond to the difference in the maximum bit line current and the minimum bit line current and may be provided to an ADC as a reference voltage that sets the input voltage range of the ADC. For example, an ADC with a VCM of 0.5V and a VREF of 0.4V can convert input voltages ranging from 0.3V to 0.7V. The VREF is determined by the conductance range of the ReRam cell. However, VREF can vary slightly across voltage and temperature, which can lead to errors in the ADC output code. The proposed circuit addresses this issue by tracking the VREF voltage in real-time to adjust the ADC input range, thereby reducing sensitivity to slight variations in the read driver output.

FIG. 5 is a block diagram depicting an example tracking circuit 500 in accordance with a further implementation of the present disclosure. Tracking circuit 500 may track and compensate for leakage current in a crossbar array, ensuring that the read-out circuits connected to the crossbar array accurately sense only the current flowing through the accessed cell.

One or more cross-point devices of the core array (e.g., crossbar array 105 of FIG. 1) are selected for programming, performing an in-memory computing operation, implementing a memory application, etc. and may be referred to as the accessed or selected cross-point devices. When a WL voltage is applied to the selected devices, unintended currents might flow through unselected cross-point devices (inactive cells). The unintended currents may be referred to as the leakage currents. Tracking circuit 500 may track the leakage current of the inactive cells, which varies across PVT.

The tracking circuit utilizes a replica bit line (BL) to generate a current I_Leak*(N) that tracks the array leakage current. The replica bit line is not part of the core array. More particularly, for example, the cross-point device connected to the bit line BL<0> and the word line WL<0> may be selected for programming, performing an in-memory computing operation, and/or implementing a memory application and may be referred to as the accessed or selected cross-point device. The current passing through the selected cross-point device (the accessed cell) is referred to as I_Read. The read-out circuit is connected to the bit line BL<0> to sense and measure the current flowing through the selected cross-point device. That is, the output of the read-out circuit is expected to correspond to I_Read. However, the leakage current may flow through the inactive cells (e.g., the cross-point devices connected to BL<0> but are not connected to WL<0>) and may contribute to the current measured by the read-out circuit. That is, the output of the read-out circuit may correspond to the combination of I_Read and the leakage current.

The tracking circuit 500 may produce a current I_Leak*(N) that corresponds to the leakage current associated with the inactive cells connected to the active bit line BL<0>. This current is then mirrored onto the active BL (e.g., BL<0>) (e.g., by a current mirror) to offset the leakage current. By generating a mirrored leakage current (I_Leak,mirrored*(N)) and applying the mirrored leakage current to the active bit line, the tracking circuit 500 can offset the leakage in the active bit line. This ensures that the read driver accurately senses only the read current from the accessed cell, thereby improving the reliability and accuracy of the read operation.

FIG. 6 is a block diagram depicting an example tracking circuit 600 in accordance with a further implementation of the present disclosure.

In some embodiments, a converter 143 may perform weight-to-pulse width conversion using a level-crossing detector, such as a comparator 610. Tracking circuit 600 may compensate for variations in voltage and temperature that affect the cell conductance and may ensure consistent pulse width generation.

When performing weight-to-pulse width conversion, a voltage level crossing detector compares the discharge read voltage to a triggering threshold voltage 611 and produces a pulse width signal (Tpulsei) based on the comparison. Variations in voltage and temperature affect the cell conductance, leading to changes in the discharge speed. Without the tracking mechanisms, the triggering threshold voltage remains constant, and pulse widths for the same conductance would be varying.

The tracking circuit 600 may generate the triggering threshold voltage 611 from the replica array, which experiences identical voltage and temperature fluctuations. The decreased threshold voltage compensated for the quicker discharging speed, resulting in consistent pulse widths.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, the use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a crossbar array comprising:
a plurality of bit lines intersecting with a plurality of word lines; and
a plurality of cross-point devices, wherein each of the plurality of cross-point devices is connected to at least one of the plurality of word lines and at least one of the plurality of bit lines;
a read-out circuit selectively connected to at least one of the bit lines, wherein the read-out circuit is configured to generate an output representative of the memristor conductance;
a tracking circuit comprising a first replica cell that emulates at least one of the plurality of cross-point devices, wherein the tracking circuit is configured to produce a reference voltage; and
a converter configured to convert the output of the read-out circuit into a digital output or a pulse-width-modulated signal, wherein the reference voltage is provided to the converter as an input.

2. The apparatus of claim 1, wherein the converter comprises an ADC, and wherein the reference voltage is provided to the ADC as a common mode voltage.

3. The apparatus of claim 2, wherein the tracking circuit further comprises a read driver replica configured to generate an output representative of a current flowing through the first replica cell, wherein the read driver replica emulates the read-out circuit.

4. The apparatus of claim 3, wherein the first replica cell is connected to a word line of the plurality of word lines and a bit line that is not one of the bit lines in the crossbar array.

5. The apparatus of claim 4, wherein the first replica cell is programmed to a conductance value corresponding to the mid-level conductance of the plurality of cross-point devices.

6. The apparatus of claim 1, wherein the converter comprises an ADC, and wherein the reference voltage represents the full voltage range of the ADC.

7. The apparatus of claim 6, wherein the tracking circuit further comprises:
a second replica cell;
a first read driver replica configured to generate a first output representative of a first current flowing through the first replica cell; and
a second read driver replica configured to generate a second output representative of a second current flowing through the second replica cell;
wherein the second current is subtracted from the first current to produce a difference current representative of a difference between the maximum bit line current and the minimum bit line current on a bit line of the plurality of bit lines.

8. The apparatus of claim 7, wherein the first replica cell is programmed to a conductance representing the maximum conductance of cross-point devices connected to the bit line of the plurality of bit lines.

9. The apparatus of claim 8, wherein the second replica cell is programmed to conductance representing the minimum conductance of cross-point devices connected to the bit line of the plurality of bit lines.

10. The apparatus of claim 7, wherein the first replica cell and the second replica cell are connected to a word line of the plurality of word lines.

11. The apparatus of claim 10, wherein the first replica cell is connected to a first bit line, wherein the second replica cell is connected to a second bit line, wherein the first bit line and the second bit line are not one of the plurality of bit lines in the crossbar array.

12. The apparatus of claim 1, wherein the converter comprises a pulse width modulator and wherein the reference voltage is provided to the pulse width modulator as a triggering threshold voltage.

13. An apparatus, comprising:
a crossbar array comprising:
a plurality of bit lines intersecting with a plurality of word lines; and
a plurality of cross-point devices, wherein each of the plurality of cross-point devices is connected to at least one of the plurality of word lines and at least one of the plurality of bit lines;
a tracking circuit comprising a replica array that emulates a group of the plurality of cross-point devices that are connected to an active bit line of the plurality of bit lines, wherein the tracking circuit is configured to produce a current representative of a leakage current on the active bit line and mirror the current representative of a leakage current on the active bit line onto the active bit line;
a read-out circuit connected to the active bit line, wherein the read-out circuit is configured to generate an output representative of a bit line current on the active bit line; and
a converter configured to convert the output of the read-out circuit into a digital output or a pulse-width-modulated signal.

14. The apparatus of claim 13, wherein the leakage current on the active bit line corresponds to currents flowing through one or more inactive cross-point devices that are connected to the active bit line.

15. The apparatus of claim 14, wherein the bit line current on the active bit line does not include the currents flowing through the inactive cross-point devices that are connected to the active bit line.
